(19) United States
(12) Patent Application Publication
(10) Pub. No.: US 2011/0140229 A1
(43) Pub. Date: Jun. 16, 2011

(54) TECHNIQUES FOR FORMING SHALLOW TRENCH ISOLATION

(76) Inventors: Willy Rachmady, Beaverton, OR (US); Been-Yih Jin, Lake Oswego, OR (US); Ravi Pillarisetty, Portland, OR (US); Robert S. Chau, Beaverton, OR (US)

(21) Appl. No.: 12/639,451

(22) Filed: Dec. 16, 2009

(51) Int. Cl. H01L 29/06; H01L 21/762

(52) U.S. Cl. 257/506; 438/424; 257/E29.02; 257/E21.546

(57) ABSTRACT

Techniques are disclosed for shallow trench isolation (STI). The techniques can be used to form STI structures on any number of semiconductor materials, including germanium (Ge), silicon germanium (SiGe), and III-V material systems. In general, an interfacial passivation layer is used as a liner between the semiconductor surface (such as diffusion) and isolation materials within the STI. The interfacial layer provides a passivation layer on trench surfaces to restrict free bonding electrons of the substrate material. In addition, this passivation layer is oxidized, thereby effectively forming a bi-layer (passivation and oxidation sub-layers) to form an electrically defect free interface. The interfacial bi-layer structure can be implemented, for example, with materials that will covalently bond with free bonding electrons of the substrate materials, and that will oxidize to provide transition to oxide material.

### FIELD OF THE DISCLOSURE

The present disclosure relates to semiconductors, and more particularly, to techniques for forming shallow trench isolation with reduced leakage and voids.

### BACKGROUND

Shallow trench isolation (STI) is a common semiconductor process employed to isolate two neighboring portions of a substrate or structure formed thereon. STI can be carried out, for example, early on in the fabrication of a semiconductor device prior to the formation of transistors or other components, such as on a blank substrate. STI can also be carried out at some later time in the fabrication process when at least some portion of a semiconductor structure is formed.

STI generally includes etching one or more trenches in the substrate (such as a blank substrate, or a partially completed semiconductor structure such as quantum well growth structure), and then depositing dielectric materials (such as silicon dioxide) to fill the trenches. The excess dielectric material can then be removed using chemical-mechanical planarization (CMP). While STI is generally an effective isolation technique, it is associated with some non-trivial problems.

### BRIEF DESCRIPTION OF THE DRAWINGS

FIGS. 1 through 6 illustrate formation of a shallow trench isolation structure configured in accordance with an embodiment of the present invention.

FIG. 7 illustrate problems associated with an example shallow trench isolation implemented with conventional techniques.

FIG. 8 illustrates a method for forming a shallow trench isolation structure in accordance with an embodiment of the present invention.

FIG. 9 illustrates a system configured with an integrated circuit having shallow trench isolation as described herein, in accordance with an embodiment of the present invention.

### DETAILED DESCRIPTION

Techniques are disclosed for shallow trench isolation (STI). The techniques can be used to form STI structures on any number of semiconductor materials, including germanium (Ge), silicon germanium (SiGe), and III-V material systems. In general, an interfacial passivation layer is used as a liner between the semiconductor surface (such as diffusion) and isolation materials within the STI.

General Overview

As previously stated, STI is associated with some non-trivial problems. For instance, STIs can be associated with high STI edge leakage, such as leakage path between gate, source, and/or drain regions of a transistor device. STIs can also be associated with voids. For instance, the aspect ratio between height and pitch in STI regions of a growth structure is typically larger than that in active areas of that structure. As such, voids tend to form above STI areas more readily than in active areas. Such problems can be exacerbated depending upon the material systems employed.

For instance, semiconductor materials such as germanium (Ge), silicon germanium (SiGe), and III-V materials generally lack thermally and electrically stable native oxides. Consider, for example, a Ge substrate in which are formed one or more STI structures. In such cases, GeO₂ (and its sub-oxide GeOₓ, where x<2) is formed naturally at the interface between the Ge and trench oxide material due to exposure of Ge surfaces to atmosphere and/or during trench oxide (e.g., SiO₂) deposition. GeO₂ is a source of electronic states/traps, and it can also readily desorb during a high temp process, thereby degrading the microstructure at the interface. In the case of a transistor device, for example, this can lead to a high leakage path between gate, source, and/or drain regions.

Thus, and in accordance with an embodiment of the present invention, STI structures formed in semiconductor materials such as Ge, SiGe, and III-V material substrates are fabricated with an interfacial layer between the semiconductor surface and isolation oxide. The interfacial layer provides a passivation layer on trench surfaces (bottom and sides) to restrict free bonding electrons of the substrate material. In addition, this passivation layer is oxidized, thereby effectively forming a bi-layer (passivation and oxidation sub-layers) to form an electrically defect free interface.

The interfacial bi-layer structure can be implemented, for example, with materials that will covalently bond with free bonding electrons of the substrate materials, and that will oxidize to provide transition to oxide material. In one example case, where the substrate is Ge, the interfacial structure can be implemented an epitaxial growth of silicon that is subsequently oxidized to provide a bi-layer of Si/SiO₂, where the Si growth acts as the passivation layer and covalently bonds with free bonding electrons of Ge atoms at the trench surfaces, and the SiO₂ is the native oxide that provides transition to SiO₂ material that can be subsequently deposited into the trenches.

As used herein, free bonding electrons refer to surface electronic states/traps. In general, surface electronic states/traps are formed because there are unpaired electrons on the surface, sometimes called dangling bonds, because they are not involved in bonding between neighboring atoms. In this sense, the passivation material of the interfacial structure is intended to remove surface electronic states/traps (at surfaces of STI structures) by tying up unpaired electrons.

Numerous material systems that can benefit from the techniques described herein will be apparent in light of this disclosure, and the claimed invention is not intended to be limited to any particular one or set. Rather, the techniques can be employed wherever STI leakage and voids are at issue, and can be resolved with an interfacial structure of the shallow trench isolation. The techniques can be embodied, for example, in any number of substrate circuits, such as fin-based field effect transistor (FET) structures (e.g., double-gate and tri-gate FinFETs) and quantum well growth structures (e.g., transistors and other active junction semiconductor devices, and any other devices that require electrical and thermal isolation between structures formed on a substrate), as well as in methodologies suitable for practice at fabs where integrated circuits are made.

Interfacial Structure

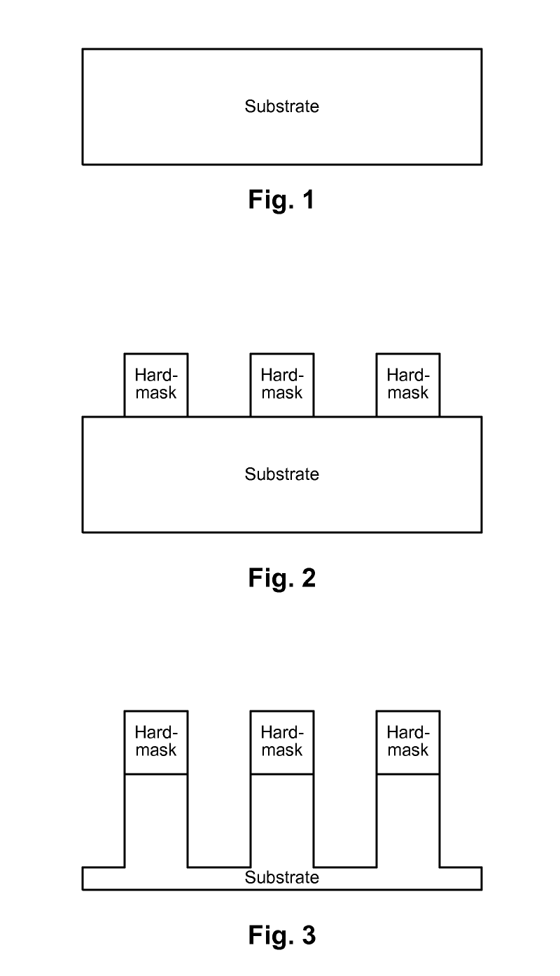

FIGS. 1 through 6 illustrate formation of a shallow trench isolation configured in accordance with an embodiment of the present disclosure.

As can be seen in FIG. 1, a substrate of some kind is provided. The substrate can be, for example, a blank substrate that is to be prepared for subsequent semiconductor processes by forming a number of STI structures therein. Alternatively, the substrate can be a partially formed semiconductor growth structure, such as a quantum well structure formed up to the contact layer, upon which drain/source contacts and a gate electrode are to be formed using at least one STI structure.

Any number of suitable substrates can be used here, including bulk substrates, semiconductors on insulator substrates (XOI, where X is a semiconductor material such as Ge or Ge-enriched Si), and multi-layered structures, and particularly those substrates including materials that generally lack thermally and electrically stable native oxides, such as those previously mentioned (e.g., Ge, SiGe, and III-V materials). In one specific example case, the substrate is a Ge bulk substrate. In another specific example case, the substrate is a Ge contact layer of quantum well or other growth structure. Any number of configurations can be used, as will be apparent.

FIG. 2 illustrates deposition and patterning of a hardmask on the substrate of FIG. 1, in accordance with one embodiment of the present invention. This can be carried out using standard photolithography, including deposition of hardmask material (e.g., such as silicon dioxide, silicon nitride, and/or other suitable hardmask materials), selectively depositing resist on a portion of the hardmask that will remain temporarily to protect an underlying region of the device (such as a diffusion or active area of a transistor device), etching to remove the unmasked (no resist) portions of the hardmask (e.g., using a dry etch, or other suitable hardmask removal process), and then stripping the selectively deposited resist, thereby leaving the patterned mask as shown.

In the example embodiment shown in FIG. 2, the resulting hardmask includes three locations, but in other embodiments, the hardmask may be configured differently, depending on the particular active device. In one specific example embodiment having a Ge substrate, the hardmask is implemented with silicon nitride. Any number of hardmask configurations can be used, as will be apparent.

As can be seen in FIG. 3, shallow trenches are etched into the substrate. The etching can be accomplished with a wet or dry etch, or a combination of etches if so desired. The geometry of the trenches (width, depth, shape, etc) can vary from one embodiment to the next as will be appreciated, and the claimed invention is not intended to be limited to any particular type of trench geometry. In one specific example embodiment having a Ge substrate and a hardmask implemented with silicon nitride, a dry etch is used to form the trenches that are about 50 Å to 5000 Å below the top surface of the substrate. Any number of trench configurations can be used, as will be apparent.

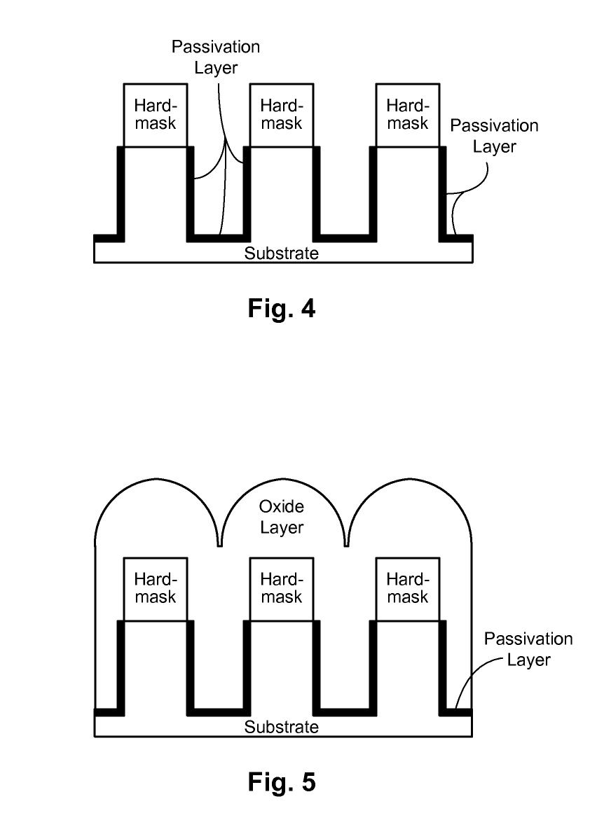

As can be seen in FIG. 4, a relatively thin passivation layer is formed on the trench surfaces, thereby protecting those surfaces from oxidation. In addition, the passivation layer eliminates or otherwise reduces state/trap densities on the trench sidewall surfaces, and may further be thermally stable, in accordance with some embodiments.

In one specific example embodiment having a Ge substrate, the passivation layer is Si film epitaxially grown on the Ge surfaces of the trench or trenches. The thickness of this Si growth can be, for example, a monolayer to 40 Å thick. In general, the thickness of the passivation layer need only be sufficient to restrict free bonding electrons at the trench surfaces. In this example case, the epitaxial Si film is covalently bonded to all trench surface Ge atoms, so that there are no state/trap densities on the trench sides and bottom surfaces, and is thermally stable. This relatively thin Si passivation layer is then partially oxidized to SiO₂. This oxidation can be carried out, for example, by flowing O₂ and O₃ into the passivation layer area, and/or exposing the passivation layer to atmosphere for a brief period (e.g., 15 seconds to 120 minutes). In one specific example embodiment, oxidation is achieved by exposing the Si passivation layer to ozone (O₃) for 15-120 seconds. In another specific example embodiment, oxidation is achieved by exposing the Si passivation layer to O₂ for 60-120 minutes, at room temperature. Any number of suitable oxidation processes can be used here, as will be appreciated in light of this disclosure. The oxidation effectively forms a Si/SiO₂ bi-layer on the Ge trench surfaces. The bi-layer passivation can be subsequently polished and/or shaped (e.g., via wet or dry etch), if so desired.

Note that the gate trench may be circular or polygonal in nature, and reference to trench ‘sides’ is intended to refer to any such configurations, and should not be interpreted to imply a particular geometric shaped structure. For instance, ‘sides’ may refer to different locations on a circular-shaped trench or discrete sides of a polygonal-shaped trench or even different locations on one discrete side of a polygonal-shaped trench. In a more general sense, ‘surfaces’ refers to all such trench sides and the base of the trench.

FIG. 5 shows how the trenches are subsequently filled with an oxide material, using any number of standard deposition processes. In one specific example embodiment having a Ge substrate and a Si/SiO₂ passivation layer, the deposited oxide material is SiO₂ film, but any number suitable isolation oxides can be used here. In general, the deposited or otherwise grown isolation oxide for filling the trenches can be selected based on compatibility with the native oxide of the passivation layer.

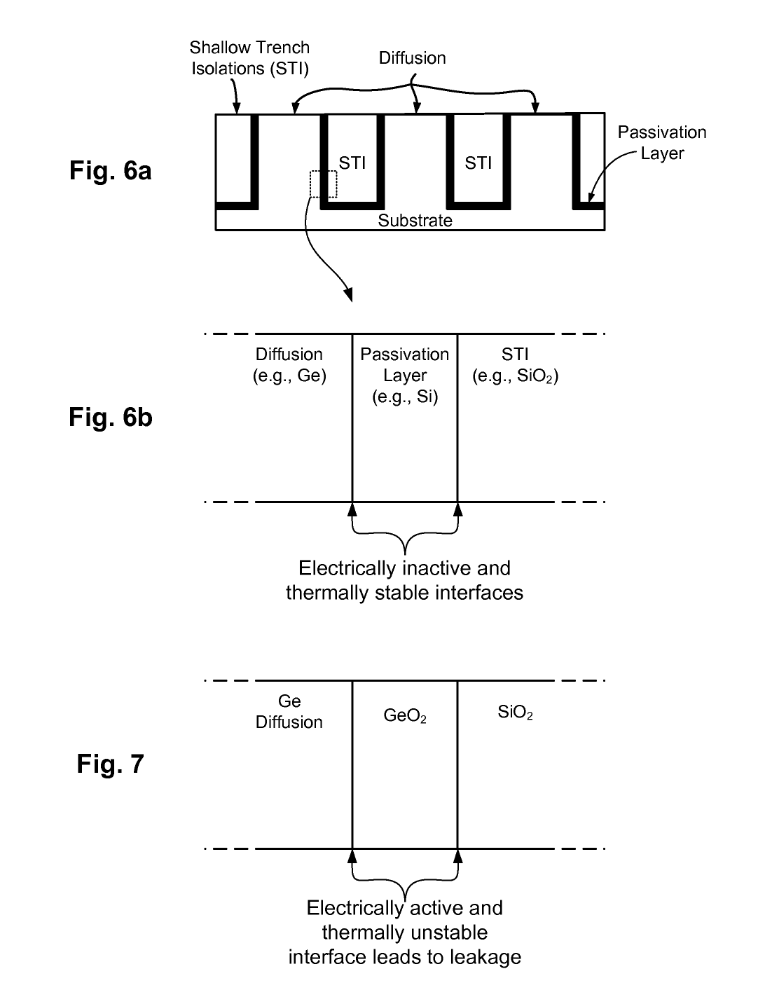

FIG. 6a demonstrates how the isolation oxide is then planarized using, for example, CMP or other suitable polish process capable of planarizing the structure. In the specific example embodiment shown, the planarization effectively forms Ge diffusion areas (e.g., such as those associated with the drain, source, and gate of a metal oxide semiconductor (MOS) transistor device), which are surrounded by STI oxide. As can be seen in expanded view of FIG. 6b, since the diffusion edges are passivated with the Si/SiO₂ passivation bi-layer, there is no leakage path along these edges. Thus, electrically inactive and thermally stable diffusion/isolation interfaces are provided.

In contrast, and as can be seen with the conventional interface of FIG. 7, GeO₂ and its sub-oxide GeOₓ (where x<2) is formed naturally at the interface between the Ge diffusion and the SiO₂ trench oxide material due to exposure of Ge surfaces to atmosphere and/or during trench oxide (SiO₂) deposition. As previously explained, GeO₂ is a source of electronic states/traps, and can readily desorb during a high temp process, thereby degrading the microstructure at the interface. Thus, an electrically active and thermally unstable diffusion/isolation interface results. In the case of a transistor device such as a FinFET, for example, such an interface can lead, for instance, to leakage between gate, source, and/or drain regions.

Methodology

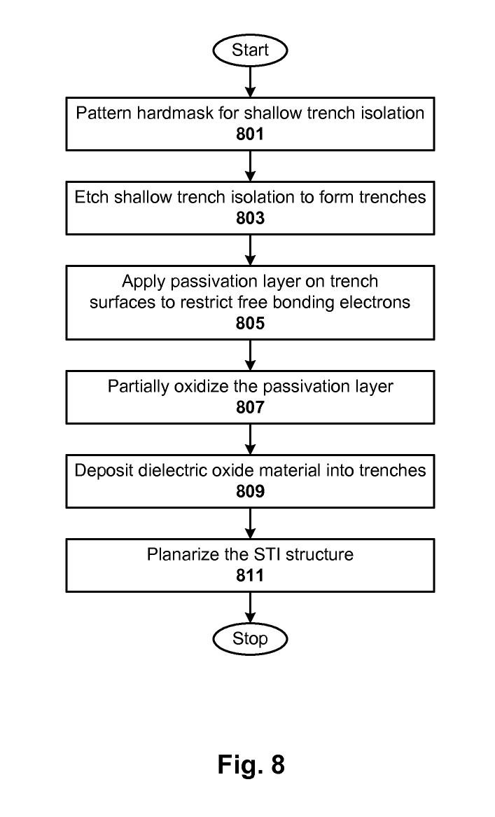

FIG. 8 illustrates a method for forming a shallow trench isolation structure in accordance with an embodiment of the present invention. The resulting STI structure can be formed, for example, in a substrate of any kind as previously explained (e.g., bulk substrate, XOI, or partially fabricated growth structure).

The method includes patterning 801 a hardmask for shallow trench isolation, and etching 803 to form one or more relatively shallow trenches. Such patterning and etching can be carried out as commonly done, using any number of known techniques, equipment and/or semiconductor materials, as will be apparent in light of this disclosure. As will be appreciated, the hardmask materials employed can be varied depending of particulars of the subsequent etch process, and the etching can be wet or dry, or a combination of wet or dry etches. In general, the patterning 801 and etching 803 can be implemented in any suitable fashion to create a number of trenches.

The method further includes applying 805 a passivation layer on trench surfaces to restrict free bonding electrons. The passivation layer can be, for example, epitaxially grown or otherwise formed on the trench sides and base surfaces, so as to protect these surfaces from oxidation. In some embodiments, the passivation layer is covalently bonded to trench surface atoms, so that there are no state/trap densities or otherwise free bonding electrons on those trench surfaces, and is thermally stable.

The method further includes partially oxidizing 807 the passivation layer, thereby forming a bi-layer of passivation material (the initial passivation material) and oxidized passivation material. This bi-layer can be, for example, Si and SiO₂, or any other suitable passivation material that can be formed on the trench surface as well as its native or otherwise compatible oxide.

The method further includes depositing 809 dielectric oxide material into the trenches. As previously explained, this dielectric oxide can be any material that is native or otherwise comparable to the oxide of the passivation layer. The method may further continue with planarizing 811 the STI structure, for example, to form isolated diffusion areas as shown in FIG. 6a

Thus, the STI structure described herein can be formed with numerous semiconductor substrates (such as Ge, SiGe/Ge, and III-V material systems). The process flow allows for forming a passivation layer that restricts free bonding electrons by operation of covalent bonding, thereby significantly improving leakage through the STI interface. The resulting STI structure can include a bi-layer of an initial passivation material and an oxidation thereof, so as to restrict free bonding electrons at the trench surface. In contrast, conventional trench/oxide isolation interfaces are electrically active and thermally unstable, as there are free bonding electrons left unrestricted.

System

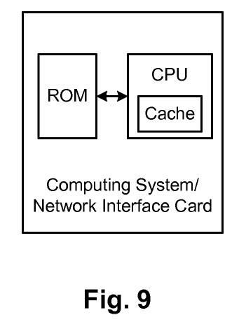

FIG. 9 illustrates a system configured with an integrated circuit device having a shallow trench isolation structure as described herein, in accordance with an embodiment of the present invention. The system can be, for example, a computing system (e.g., laptop or desktop computer, server, smart phone, etc) or a network interface card or any other system that employs integrated circuitry having shallow trench isolation structures. As will be appreciated, integrated circuit technology having a shallow trench isolation structure effectively has an almost unlimited number of applications at the system level, such as those involving transistors, and the specific system shown is merely provided as an example. The integrated circuit device may be included in any components of the system, such as in the processor or ROM (or other memory), and/or logic circuitry of the system.

As can be seen, this example system generally includes a ROM and central processing unit (CPU, or processor) configured with on-chip cache. Any suitable processor can be used, such as those provided by Intel Corporation (e.g., Intel® Core™, Pentium®, Celeron®, and Atom™ processor families). The processor can access its cache and/or the ROM and execute functionality particular to a given application, as commonly done. In accordance with an embodiment of the present invention, each of the processor, ROM and/or on-chip cache can be implemented using shallow trench isolation structures configured with a passivation layer as described herein. Other system componentry (such as display, keypad, random access memory, co-processors, bus structures, etc) are not shown, but will be apparent given the particular system application at hand.

Numerous embodiments and configurations will be apparent in light of this disclosure. For instance, one example embodiment of the present invention provides a method for forming a shallow trench isolation structure. The method includes etching to form a trench for shallow trench isolation on a semiconductor substrate, the trench having side and bottom surfaces. The method further includes applying a passivation layer on the surfaces of the trench to restrict free bonding electrons at those trench surfaces. The method may further include partially oxidizing the passivation layer, thereby forming a bi-layer of passivation material and oxidized passivation material. In one such example case, the substrate includes germanium, the passivation material is silicon, and the oxidized passivation material is silicon dioxide. The may include at least one of: prior to etching, patterning a hardmask for shallow trench isolation; depositing dielectric oxide material into the trench, thereby providing an STI structure; and planarizing the STI structure. The method can be carried out, for example, on at least one of a blank substrate and a partially fabricated semiconductor growth structure (e.g., to provide STI structures on a blank substrate, and then again on that substrate once some partially grown semiconductor structure is formed using the substrate). In some example cases, the passivation layer is epitaxially grown on the trench surfaces. In another example case, the passivation layer covalently bonds to surface atoms on the trench surfaces. In one such particular case, the passivation layer is thermally stable.

Another example embodiment of the present invention provides an integrated circuit device. The device includes a semiconductor substrate having one or more trenches etched therein, each trench having side and bottom surfaces. The device further includes a passivation layer on the surfaces of each trench to restrict free bonding electrons at those trench surfaces. The passivation layer may be partially oxidized, thereby forming a bi-layer of passivation material and oxidized passivation material. In one such particular case, the substrate includes germanium, the passivation material is silicon, and the oxidized passivation material is silicon dioxide. In some embodiments, the device includes a dielectric oxide material deposited into each trench, thereby providing one or more STI structures, wherein the one or more STI structures are planarized. The substrate can be, for example, a blank substrate and/or a partially fabricated semiconductor growth structure (where the substrate is initially blank and has STI structures formed thereon, and then subsequently has a semiconductor growth structure formed thereon that includes additional STI structures). In some example cases, the passivation layer can be epitaxially grown on the trench surfaces and/or covalently bonds to surface atoms on the trench surfaces. In other example cases, the device is integrated into a system including at least one of a processor, memory, and/or logic circuit.

Another example embodiment of the present invention provides a method for forming a shallow trench isolation structure. The method includes etching to form one or more trenches for shallow trench isolation on a semiconductor substrate, each trench having side and bottom surfaces. The method further includes epitaxially growing a passivation layer on the surfaces of each trench to restrict free bonding electrons at those trench surfaces. The method further includes partially oxidizing the passivation layer, thereby forming a bi-layer of passivation material and oxidized passivation material. In some such cases, the substrate includes germanium, the passivation material is silicon, and the oxidized passivation material is silicon dioxide. In another such case, the method is carried out on at least one of a blank substrate and a partially fabricated semiconductor growth structure. In another such case, the passivation layer covalently bonds to surface atoms on the trench surfaces, and is thermally stable. The method may include depositing dielectric oxide material into the trench, thereby providing an STI structure, and/or planarizing the STI structure.

The foregoing description of example embodiments of the invention has been presented for the purposes of illustration and description. It is not intended to be exhaustive or to limit the invention to the precise forms disclosed. Many modifications and variations are possible in light of this disclosure. It is intended that the scope of the invention be limited not by this detailed description, but rather by the claims appended hereto.

What is claimed is:

1. A method for forming a shallow trench isolation structure, comprising:
etching to form a trench for shallow trench isolation on a semiconductor substrate, the trench having side and bottom surfaces; and
applying a passivation layer on the surfaces of the trench to restrict free bonding electrons at those trench surfaces.

2. The method of claim 1 further comprising:
partially oxidizing the passivation layer, thereby forming a bi-layer of passivation material and oxidized passivation material.

3. The method of claim 2 wherein the substrate includes germanium, the passivation material is silicon, and the oxidized passivation material is silicon dioxide.

4. The method of claim 1 further comprising at least one of:
prior to etching, patterning a hardmask for shallow trench isolation;
depositing dielectric oxide material into the trench, thereby providing an STI structure; and
planarizing the STI structure.

5. The method of claim 1 wherein the method is carried out on at least one of a blank substrate and a partially fabricated semiconductor growth structure.

6. The method of claim 1 wherein the passivation layer is epitaxially grown on the trench surfaces.

7. The method of claim 1 wherein the passivation layer covalently bonds to surface atoms on the trench surfaces.

8. The method of claim 8 wherein the passivation layer is thermally stable.

9. An integrated circuit device, comprising:
a semiconductor substrate having one or more trenches etched therein, each trench having side and bottom surfaces; and
a passivation layer on the surfaces of each trench to restrict free bonding electrons at those trench surfaces.

10. The device of claim 9 wherein the passivation layer is partially oxidized, thereby forming a bi-layer of passivation material and oxidized passivation material.

11. The device of claim 10 wherein the substrate includes germanium, the passivation material is silicon, and the oxidized passivation material is silicon dioxide.

12. The device of claim 9 further comprising:
a dielectric oxide material deposited into each trench, thereby providing one or more STI structures, wherein the one or more STI structures are planarized.

13. The device of claim 9 wherein the substrate is at least one of a blank substrate and a partially fabricated semiconductor growth structure.

14. The device of claim 9 wherein the passivation layer is epitaxially grown on the trench surfaces and covalently bonds to surface atoms on the trench surfaces.

15. The device of claim 9 wherein the device is integrated into a system including at least one of a processor, memory, and/or logic circuit.

16. A method for forming a shallow trench isolation structure, comprising:
etching to form one or more trenches for shallow trench isolation on a semiconductor substrate, each trench having side and bottom surfaces;
epitaxially growing a passivation layer on the surfaces of each trench to restrict free bonding electrons at those trench surfaces; and
partially oxidizing the passivation layer, thereby forming a bi-layer of passivation material and oxidized passivation material.

17. The method of claim 16 wherein the substrate includes germanium, the passivation material is silicon, and the oxidized passivation material is silicon dioxide.

18. The method of claim 16 further comprising:
depositing dielectric oxide material into the trench, thereby providing an STI structure; and
planarizing the STI structure.

19. The method of claim 16 wherein the method is carried out on at least one of a blank substrate and a partially fabricated semiconductor growth structure.

20. The method of claim 16 wherein the passivation layer covalently bonds to surface atoms on the trench surfaces, and is thermally stable.
